(19) United States
(12) Patent Application Publication
(10) Pub. No.: US 2021/0195743 A1
(43) Pub. Date: Jun. 24, 2021

(54) MULTILAYER CONSTRUCTION FOR MOUNTING LIGHT EMITTING DEVICES

(71) Applicant: 3M INNOVATIVE PROPERTIES COMPANY

(72) Inventors: Donato G. Caraig, Singapore (SG); Choong Meng How, Singapore (SG); Ravi Palaniswamy, Singapore (SG); Alejandro Aldrin A. Narag, II, Singapore (SG); Bing Liu, Singapore (SG)

(21) Appl. No.: 16/077,804

(22) PCT Filed: Feb. 15, 2017
(86) PCT No.: PCT/US2017/017870

§ 371 Date: Aug. 14, 2018

(51) Int. Cl. H05K 1/11; H05K 1/02; H05K 3/10

(52) U.S. Cl. CPC H05K 1/118; H05K 1/111; H05K 2201/2054; H05K 3/107; H05K 2201/10106; H05K 1/0274

(57) ABSTRACT

A flexible multilayer construction is configured for mounting an electronic device. The flexible multilayer construction includes electrically conductive spaced apart first and second pads for electrically connecting to corresponding electrically conductive first and second terminals of the electronic device. The first and second pads define a capillary groove therebetween that is at least partially filled with an electrically insulative reflective material by a capillary action.

### TECHNICAL FIELD

This disclosure relates generally to constructions upon which light emitting devices can be mounted, and to systems and methods related to such constructions.

### BACKGROUND

Light emitting devices (LEDs) and/or other devices can be mounted on a substrate cut or formed into single or multi-device units. Electrically conductive pads disposed on the substrate are electrically connected to terminals of the LED.

### BRIEF SUMMARY

A flexible multilayer construction for mounting a light emitting semiconductor device (LESD) includes a flexible dielectric substrate comprising opposing top and bottom major surfaces and an LESD mounting region on the top major surface. Electrically conductive spaced apart first and second pads are disposed in the LESD mounting region for electrically connecting to corresponding electrically conductive first and second terminals of an LESD received in the LESD mounting region. The first and second pads define a groove therebetween having a maximum width less than about 250 microns and a maximum depth d. An electrically insulative reflective material at least partially fills the groove to a maximum thickness greater than about 0.7d and less than about 1.2d and a maximum width less than about 270 microns.

Some embodiments involve a flexible multilayer system for being divided into a plurality of flexible multilayer constructions. Each flexible multilayer construction is configured for mounting a different light emitting semiconductor device. The flexible multilayer system includes a flexible dielectric substrate comprising opposing top and bottom major surfaces. An electrically conductive layer is formed on the top major surface of dielectric substrate. The conductive layer defines one or more spaced apart parallel wider first grooves extending lengthwise along a first direction and one or more spaced apart parallel narrower second grooves extending lengthwise along an orthogonal second direction. Each narrower second groove fluidically communicates with at least one wider first groove. Each first and second groove is at least partially filled with an electrically insulative reflective material.

Some embodiments are directed to a flexible multilayer system for being divided into a plurality of flexible multilayer constructions. Each flexible multilayer construction is configured for mounting a different light emitting semiconductor device. The flexible multilayer system includes a plurality of spaced apart parallel first grooves extending lengthwise along a first direction and a plurality of spaced apart parallel second grooves extending lengthwise along a different second direction. Each second groove is narrower than each first groove and communicates with at least one first groove. Each first and second groove is at least partially filled with an electrically insulative reflective material.

According to some embodiments, a flexible multilayer system includes a flexible dielectric substrate comprising opposing top and bottom major surfaces. A patterned electrically conductive layer is disposed on the top surface and defines a plurality of spaced apart capillary grooves. Each capillary groove has a width, w, and a depth, d. An electrically insulative reflective material is disposed within the plurality of capillary grooves. A plurality of reservoir regions is defined by the patterned electrically conductive layer. Each reservoir region is fluidically coupled to one or more of the capillary grooves. Each reservoir region is configured to hold an amount of the electrically insulative reflective material to at least partially fill the one or more capillary grooves to which it is fluidically coupled such that a maximum thickness of the reflective material in the one or more capillary grooves is greater than about 0.7d and less than about 1.2d and a maximum width of the reflective material in the one or more capillary grooves is less than about 1.1w. The width and depth of each capillary groove provides capillary movement of the electrically insulative reflective material within the capillary groove.

Some embodiments involve a flexible multilayer construction for mounting an electronic device. The flexible multilayer construction includes electrically conductive spaced apart first and second pads for electrically connecting to corresponding electrically conductive first and second terminals of an electronic device. The first and second pads define a capillary groove therebetween that is at least partially filled with an electrically insulative reflective material by a capillary action.

Some embodiments are directed to a method of fabricating one or more multilayer construction for mounting one or more light emitting semiconductor devices. A patterned electrically conductive layer is formed on a top major surface of a dielectric substrate. The patterned conductive layer defines a wider first groove and a narrower second groove communicating with the wider first groove. A solution of an electrically insulative reflective material is deposited in the wider first groove. The narrower second groove is sufficiently narrow to provide a capillary action so that the solution of the reflective material deposited in the wider first groove flows into the narrower second groove by capillary action and at least partially fills the narrower second groove.

These and other aspects of the present application will be apparent from the detailed description below. In no event, however, should the above summaries be construed as limitations on the claimed subject matter, which subject matter is defined solely by the attached claims.

### BRIEF DESCRIPTION OF THE DRAWINGS

FIG. 1A provides a cross sectional view of a flexible multilayer construction for mounting an electronic device such as an light emitting semiconductor device (LESD) in accordance with some embodiments;

FIG. 1B shows the same multilayer construction as in FIG. 1A with an LESD mounted to the multilayer construction;

FIG. 1C shows a top view of a multilayer construction in accordance with some embodiments;

FIGS. 2A and 2B illustrate a multilayer system that can be divided into a plurality of multilayer constructions for mounting a single LESD in accordance with some embodiments;

FIG. 2C depicts a multilayer construction that results from dividing the multilayer system of FIGS. 2A and 2B;

FIGS. 3A and 3B illustrate a multilayer system that can be divided into a plurality of multilayer constructions for mounting multiple LESDs in accordance with some embodiments;

FIG. 3C depicts a multilayer construction that results from dividing the multilayer system of FIGS. 3A and 3B; and

FIG. 4 is a flow diagram illustrating a method fabricating a multilayer construction for mounting one or more LESDs in accordance with some embodiments.

The figures are not necessarily to scale. Like numbers used in the figures refer to like components. However, it will be understood that the use of a number to refer to a component in a given figure is not intended to limit the component in another figure labeled with the same number.

### DESCRIPTION OF ILLUSTRATIVE EMBODIMENTS

Embodiments disclosed herein relate to constructions for mounting light emitting semiconductor devices (LESDs). In constructions configured to mount LESDs, the supporting substrate may absorb the light emitted from LESD chip. Additionally, where the LESD emits ultraviolet (UV), the UV light emitted from LESD may tend to degrade the substrate over the time, especially for LESDs that emit high intensity light. The absorption of light and/or degradation of the substrate material can be reduced by coating portions of the substrate surface with an absorption-reducing coating while leaving the electrically conductive pads substantially clear for attaching the LESDs. However, when the electrically conductive pads are closely spaced standard coating processes, such as silk screening, are suboptimal because the desired deposition resolution cannot be achieved. Embodiments disclosed herein involve approaches for applying a reflective material between the electrically conductive pads by capillary movement.

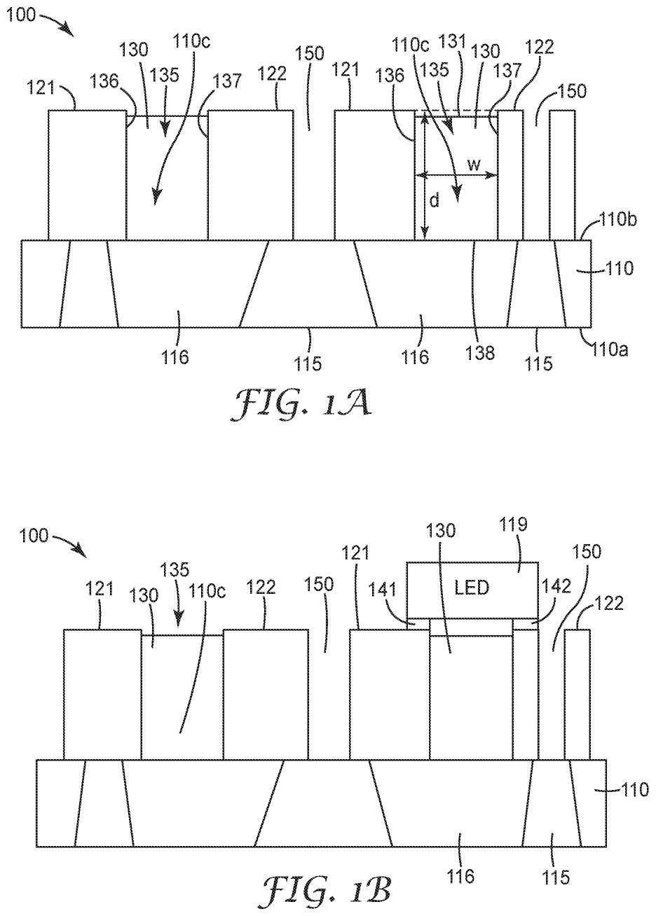

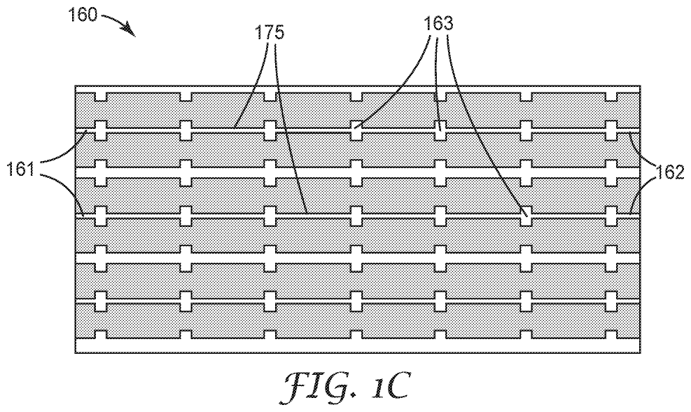

FIG. 1A provides a cross sectional view of a flexible multilayer construction 100 for mounting an electronic device such as an LESD. FIG. 1B shows the same multilayer construction 100 as in FIG. 1A with an LESD 119 mounted to construction 100. The construction 100 includes a flexible substrate 110 that includes dielectric portions 116, e.g., comprising polyimide film (PI) and may include electrically conductive portions 115, e.g., comprising copper. The flexible substrate 110 has opposing top 110b and bottom 110a major surfaces and one or more LESD mounting regions 110c on the top major surface 110b. Electrically conductive spaced apart first 121 and second 122 pads are disposed in the LESD mounting region 110c and are configured for electrically connecting to corresponding electrically conductive first and second terminals 141, 142 of an LESD 119 (see FIG. 1B). Adjacent first and second pads 121, 122 define a capillary groove 135 therebetween having a maximum width, w, and a maximum depth, d. The groove 135 is configured such that it can be at least partially filled with an electrically insulative reflective material 130 by a capillary action.

As shown in FIGS. 1A and 1B, in some embodiments, the pads 121, 122 may include fiducials 150 that facilitate positioning the LESDs 119.

In various embodiments, the maximum width of the groove 135 may be less than about 250 microns, less than about 200 microns, less than about 150 microns, less than about 100 microns, less than about 80 microns, less than about 60 microns, or even less than about 40 microns. The depth, d, of the groove may be in a range from about 10 microns to 80 microns or in a range from about 10 microns to 70 microns, for example. In some embodiments the maximum width of the filled reflective material 130 is less than about 260 microns. The maximum width of the filled reflective material 130 may be less than about 1.1w which means that the reflective material 130 may be disposed in the groove 135 and extending slightly onto the top surface of one or both electrically conductive pads 121, 122 on either side of the groove 135. In some scenarios, when the reflective material 130 is at least partially filling the groove 135, some of the reflective material 130 is disposed on a top surface of either the first and/or second pad. The placement of the reflective material 130 on the top surface of one or both electrically conductive pads 121, 122 is limited to within 30 microns, within 20 microns, or even within 15 microns of the groove 135.

The flexible multilayer construction 100 may have an average optical transmittance of less than about 25%, or less than about 20% in a visible range of the spectrum at a location on the filled reflective material 130 inside lateral edges 136, 137 of the groove 135. The flexible multilayer construction 100 may have an average optical reflectance of greater than about 70%, or greater than about 80% in a visible range of the spectrum at a location on the filled reflective material 130 inside lateral edges 136, 137 of the groove 135.

The filled reflective material 130 may increase, by at least 60%, or at least 70% an average optical transmittance of the flexible multilayer construction 100 at a location inside lateral edges 136, 137 of the groove 135. The top surface 131 of the reflective material 130 may be flat, or may be concave toward the bottom surface 138 of the groove 135, or may be convex away from a bottom surface 138 of the groove 135.

As discussed in more detail herein, in some embodiments, each capillary groove 135 may be fluidically connected to one or more reservoir regions which can be loaded with the reflective material. The reflective material deposited in the reservoir regions moves along the capillary groove by capillary forces. The reservoir regions are wider than the width, w, of the groove. For example the width of the capillary groove 135 may be at least about 70% less than the width of the reservoir regions.

FIG. 1C shows a top view of a multilayer construction 160 in accordance with some embodiments. Each capillary groove 175 extends between opposing first and second groove ends 161, 162 and is intersected by one or more reservoir regions 163. A width of the groove 175 at at least one of the first and second groove ends 161, 162 may be at least about 70% less than a width of the groove 135 at one or more points 163 between the first and second groove ends 161, 162. The wider points 163 along the grooves 175 are reservoir regions. Although multiple reservoir regions are shown in FIG. 1C, in some embodiments, only one reservoir region intersects a groove, e.g., at the midpoint of the groove between the first and second groove ends.

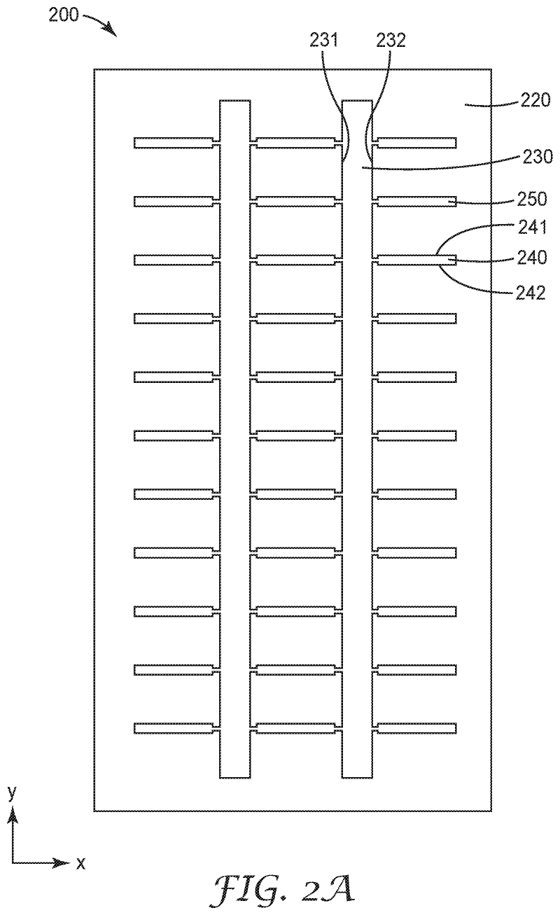

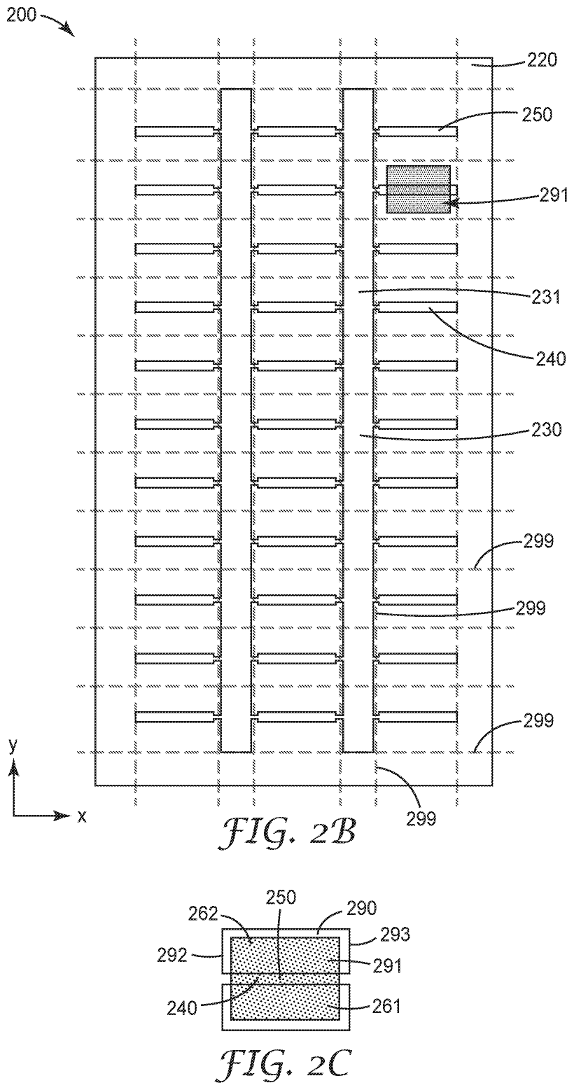

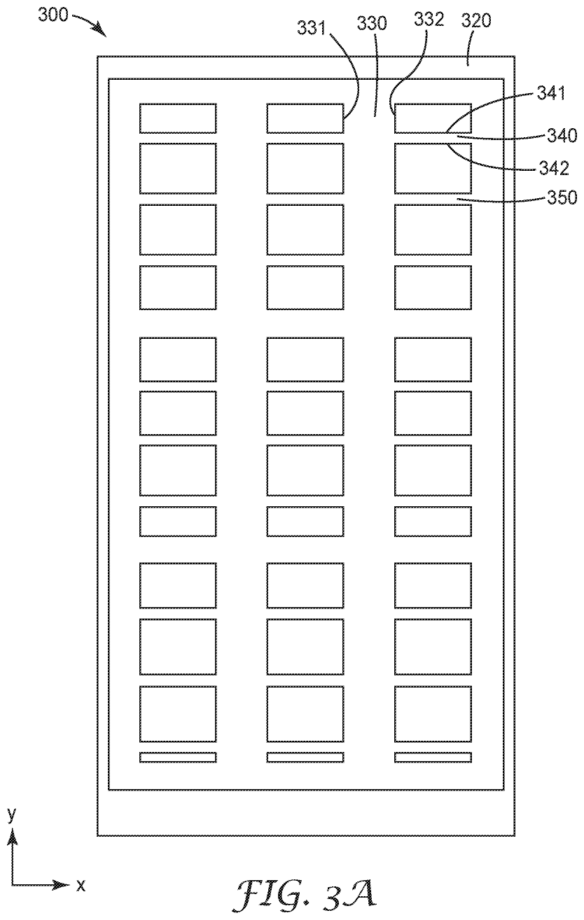

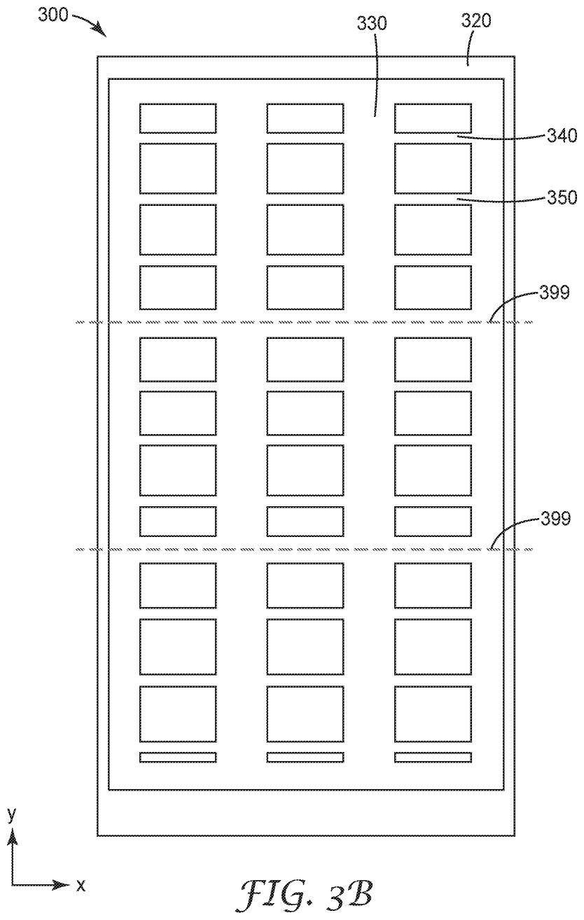

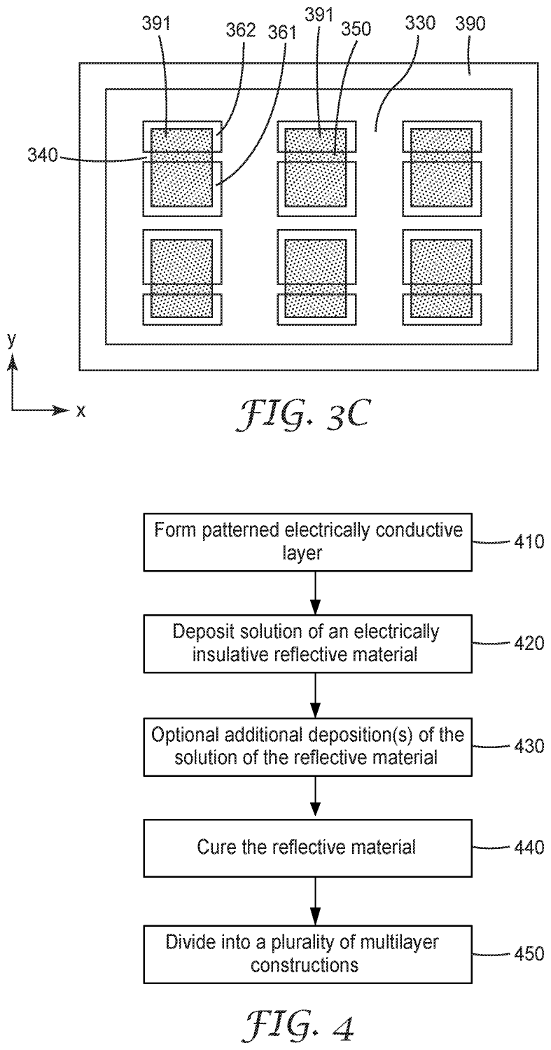

As illustrated in the top views of FIGS. 2A through 2C and 3A through 3C, a flexible multilayer system 200, 300 may be configured to be divided into a plurality of flexible multilayer constructions 290, 390. Each flexible multilayer construction 290, 390 is configured for mounting one or more different devices, e.g., one or more LESDs. A single device can be mounted on the flexible multilayer construction 290 shown in FIG. 2C. Multiple devices can be mounted on the flexible multilayer construction 390 shown in FIG. 3C.

According to some embodiments, the flexible multilayer system 200, 300 includes a flexible dielectric substrate comprising opposing top and bottom major surfaces (see FIG. 1A, elements 110, 110b, 110a). A patterned electrically conductive layer 220 is disposed on the top surface of the flexible dielectric substrate and defines a plurality of spaced apart capillary grooves 240, 340, each capillary groove 240, 340 having a width, w, and a depth, d. An electrically insulative reflective material 250, 350 is disposed within the plurality of capillary grooves 240, 340. The width and depth of each capillary groove 240, 340 supports capillary flow of the electrically insulative reflective material 250, 350 within the capillary groove 240, 340. One or more reservoir regions 230, 330 are fluidically connected to one or more of the capillary grooves 240, 340. The reservoir regions 230, 330 are shown as grooves in FIGS. 2A through 3C. However, the reservoir regions 230, 330 may have any suitable shape so long as the one or more reservoir regions 230, 330 are capable of holding an amount of the electrically insulative reflective material 250, 350 to at least partially fill the one or more capillary grooves 240, 340 to which they are fluidically connected to a maximum thickness of the reflective material greater than about 0.7d and less than about 1.2d and such that the maximum width of the reflective material is less than about 1.1w.

Each reservoir region 230, 330 has an area that is sufficiently large such that the reservoir region 230, 330 can reliably be screen printed with a solution of the reflective material 250, 350 without printing the solution beyond a lateral edge 231, 232, 331, 332 of the reservoir region 230, 330. Each capillary groove 240, 340 is sufficiently narrow that it cannot reliably be screen printed with a solution of the reflective material 250, 350 without printing the solution beyond a lateral edge 241, 242, 341, 342 of the groove 240, 340. For example, a minimum width of each wider first groove 230, 330 may be at least 400 microns in some embodiments. A maximum width of each narrower second groove 240, 340 may be at most 200 microns in some embodiments.

As illustrated in FIGS. 2A through 3C, the plurality of reservoir regions 230, 330 may comprises a plurality of spaced apart parallel wider grooves extending along a first direction (y) and the plurality of capillary grooves 240, 340 may comprise a plurality of narrower parallel grooves extending along a second (x) direction that is different from the first direction. In some embodiments, each first and second groove 230, 330, 240, 340 is filled with the reflective material 250, 350.

As best understood with reference to the cross sectional view of FIG. 1A and the top views of FIGS. 2A and 3A, the flexible multilayer system 200, 300 includes a flexible dielectric substrate 110 comprising opposing top 110b and bottom major surfaces 110b. An electrically conductive layer 220, 320 is formed on the top major surface of dielectric substrate 110. The conductive layer 220, 320 defines one or more spaced apart parallel wider first grooves 230, 330 extending lengthwise along a first (y) direction. One or more spaced apart parallel narrower second grooves 240, 340 extend lengthwise along an orthogonal second (x) direction. Each narrower second groove 240, 340 fluidically communicates with at least one wider first groove 230, 330. An electrically insulative reflective material 250, 350 at least partially fills each first 230, 330 and second 240, 340 groove.

Each first 230, 330 and second groove 240, 340 extends depthwise to the top major surface 110b of the dielectric substrate 110 (see FIG. 1A). For example, in some embodiments the one or more spaced apart parallel wider first grooves 230, 330 may comprise at least 20 spaced apart parallel wider first grooves. In some embodiments the one or more spaced apart parallel narrower second grooves 240, 340 comprises at least 50 spaced apart parallel narrower second grooves.

The flexible multilayer system 200, 300 can be divided into a plurality of flexible multilayer constructions 290, 390 by cutting along dashed lines 299, 399. Each construction 290, 390 comprises an LESD mounting region 291, 391 comprising a section of a narrower second groove 240, 340. The construction 290, 390 has a first portion 261, 361 of the conductive layer 220, 320 on a first lateral side of the second groove 240, 340 and a second portion 262, 362 of the conductive layer 220, 320 on an opposite second lateral side of the second groove 240, 340. As shown in FIG. 2C, in some implementations, the narrower second grooves 240 extend to the edges 292, 293 of the flexible multilayer construction 290. The first 261, 361 and second 262, 362 conductive portions are electrically isolated from each other and form electrically conductive spaced apart respective first and second pads for electrically connecting to corresponding electrically conductive first and second terminals of an LESD received in the LESD mounting region 291, 391. The reflective material 250, 350 at least partially fills the second groove 240, 340 and is configured to reflect light emitted by the LESD.

FIG. 4 is a flow diagram illustrating a method fabricating a multilayer construction for mounting one or more light emitting semiconductor devices (LESD) in accordance with various embodiments. A patterned electrically conductive layer is formed 410 on a top major surface of substrate comprising a dielectric material. For example, the flexible substrate may comprise one or more of polyimide (Pp, thermoplastic PI, aromatic polyamide, liquid crystal polymer (LCP), polycarbonate (PC), polyether ether ketone, polyethylene terephthalate (PET), polymethyl methacrylate (PMMA), polycyclic olefin, polysulfone (PSU), polyethylene naphthalate (PEN), epoxy resin, and thermoplastic dielectric material.

The patterned conductive layer defines a reservoir region and a capillary groove fluidically communicating with the reservoir region. Forming the patterned conductive layer may involve one or more of a lithography process, a plating process, a printing process, a coating process, and an etching process. For example, the reservoir region may comprise a wider first groove and the capillary groove may comprise narrower second groove. Each narrower second groove communicates with at least one wider first groove. For example, in some embodiments, each wider first groove extends lengthwise along a first direction and each narrower second groove extends lengthwise along a different second direction.

A solution of an electrically insulative reflective material is deposited 420 in the wider first groove, e.g., by screen printing the solution in the wider first groove. The electrically insulative reflective material may comprise one or more of epoxy, polyurethane, polyimide and polysilicon, for example. In some implementations, the solution of the electrically insulative reflective material is substantially solventless or the solution of the electrically insulative reflective material comprises less than about 5% solvent by weight.

Each narrower second groove is sufficiently narrow to provide a capillary movement of the solution so that the solution of the reflective material deposited in the wider first groove flows into the narrower second groove in communication with the wider first groove by capillary flow and at least partially fills the narrower second groove.

In some implementations, the solution of the electrically insulative reflective material may be pre-cured or otherwise pre-processed to achieve a desired viscosity before it is deposited into the wider second groove. For example, the pre-processing may be applied to electrically insulative reflective material until the viscosity of the electrically insulative reflective material is increased to about 600-800 poise or between about 500 and 800 poise. The step of pre-processing the solution increases the viscosity of the solution to a viscosity that allows both silk screening and capillary movement of the solution. In some embodiments, pre-processing the electrically insulative reflective material involves pre-curing the solution by heating the solution to a temperature in a range of about 40 to 60 degrees Celsius, e.g., about 50 degrees Celsius, or for a period of about 2 to 4 hours to increase a viscosity of the solution prior to deposition.

Optionally, the temperature of the dielectric substrate may be held at a temperature greater than a room temperature during the deposition of the reflective material into the wider first grooves (reservoir regions) and the capillary flow of the deposited reflective material into the narrower second grooves (capillary grooves). For example, the temperature of the dielectric substrate may be maintained in a range from about 30 to 80 degrees Celsius, in a range from about 40 to 70 degrees Celsius, in a range from about 45 to 70 degrees Celsius, or in a range from about 50 to 70 degrees Celsius during the deposition and/or capillary flow Maintaining the temperature of the dielectric substrate at a temperature greater than the room temperature can increase a speed of the capillary flow of the deposited reflective material into the narrower second grooves by at least a factor of 10, by at least a factor of 50, or even by at least a factor of 100.

Optionally, the electrically insulative reflective material may be deposited 430 in the wider first groove at least a second time. The solution deposited the second time further fills the narrower second groove by capillary action. The dielectric substrate may be held at a temperature greater than a room temperature during the second deposition of the reflective material in the wider first groove and the capillary flow of the deposited reflective material into the narrower second groove. Depositing the reflective material a second time increases the thickness of the reflective material in the wider first groove and the narrower second groove. However, the thickness of the reflective material may increase more in the wider first groove and less in the narrower second groove.

The reflective material cures 440 after the deposition of the reflective material in the wider first groove and the capillary flow of the deposited reflective material into the narrower second groove. In some implementations, the curing step comprises increasing a temperature of the reflective material to about 130 to about 170 degrees Celsius, or to about 140 to about 170 degrees Celsius and maintaining the increased temperature for about 1 to 3 hours. In some implementations, the curing step comprises exposing the reflective material to UV radiation.

The patterned electrically conductive layer having the reflective material disposed in the one or more wider first grooves and the one or more narrower grooves can be divided 450, e.g., by cutting, into a plurality of single or multiple device multilayer constructions. Each multilayer construction may include a section of at least one narrower second groove that is at least partially filled with the electrically insulative reflective material. In some implementations, the filled section of the narrower second groove extends to at least one of first and second edges of the flexile multilayer construction. In some implementations, the filled section of the narrower second groove extends to both first and second edges of the flexile multilayer construction.

Items disclosed herein include:

Item 1. A flexible multilayer construction for mounting a light emitting semiconductor device (LESD), comprising:

a flexible dielectric substrate comprising opposing top and bottom major surfaces and an LESD mounting region on the top major surface;

electrically conductive spaced apart first and second pads disposed in the LESD mounting region for electrically connecting to corresponding electrically conductive first and second terminals of an LESD received in the LESD mounting region, the first and second pads defining a groove therebetween having a maximum width less than about 250 microns and a maximum depth d; and

an electrically insulative reflective material at least partially filling the groove to a maximum thickness greater than about 0.7d and less than about 1.2d and a maximum width less than about 270 microns.

Item 2. The flexible multilayer construction of item 1, wherein the maximum width of the groove is less than about 200 microns.
Item 3. The flexible multilayer construction of item 1, wherein the maximum width of the groove is less than about 150 microns.
Item 4. The flexible multilayer construction of item 1, wherein the maximum width of the groove is less than about 100 microns.
Item 5. The flexible multilayer construction of item 1, wherein the maximum width of the groove is less than about 80 microns.
Item 6. The flexible multilayer construction of item 1, wherein the maximum width of the groove is less than about 60 microns.
Item 7. The flexible multilayer construction of item 1, wherein the maximum width of the groove is less than about 40 microns.
Item 8. The flexible multilayer construction of item 1, wherein d is in a range from about 10 microns to 80 microns.
Item 9. The flexible multilayer construction of item 1, wherein d is in a range from about 10 microns to 70 microns.
Item 10. The flexible multilayer construction of item 1, wherein the maximum width of the filled reflective material is less than about 260 microns.
Item 11. The flexible multilayer construction of item 1, wherein the maximum width of the groove is w and the maximum width of the filled reflective material is less than about 1.1w.
Item 12. The flexible multilayer construction of any of items 1 through 11, wherein if, when the reflective material is at least partially filling the groove, some of the reflective material is placed on a top surface of either the first or second pad, the placement is limited to within 30 microns of the groove.
Item 13. The flexible multilayer construction of any of items 1 through 11, wherein if, when the reflective material is at least partially filling the groove, some of the reflective material is placed on a top surface of either the first or second pad, the placement is limited to within 20 microns of the groove.
Item 14. The flexible multilayer construction of any of items 1 through 11, wherein if, when the reflective material is at least partially filling the groove, some of the reflective material is placed on a top surface of either the first or second pad, the placement is limited to within 15 microns of the groove.
Item 15. The flexible multilayer construction of any of items 1 through 14, wherein the reflective material at least partially fills the groove by capillary action.
Item 16. The flexible multilayer construction of any of items 1 through 15 having an average optical transmittance of less than about 25% in a visible range of the spectrum at a location on the filled reflective material inside lateral edges of the groove.
Item 17. The flexible multilayer construction of any of items 1 through 15 having an average optical transmittance of less than about 20% in a visible range of the spectrum at a location on the filled reflective material inside lateral edges of the groove.
Item 18. The flexible multilayer construction of any of items 1 through 17 having an average optical reflectance of greater than about 70% in a visible range of the spectrum at a location on the filled reflective material inside lateral edges of the groove.
Item 19. The flexible multilayer construction of any of items 1 through 17 having an average optical reflectance of greater than about 80% in a visible range of the spectrum at a location on the filled reflective material inside lateral edges of the groove.
Item 20. The flexible multilayer construction of any of items 1 through 19, wherein the filled reflective material increases, by at least 60%, an average optical transmittance of the flexible multilayer construction at a location inside lateral edges of the groove.
Item 21. The flexible multilayer construction of any of items 1 through 19, wherein the filled reflective material increases, by at least 70%, an average optical transmittance of the flexible multilayer construction at a location inside lateral edges of the groove.
Item 22. The flexible multilayer construction of any of items 1 through 21, wherein a top surface of the reflective material is convex away from a bottom surface of the groove.
Item 23. The flexible multilayer construction of any of items 1 through 22, wherein the groove extends between opposing first and second groove ends, a width of the groove at at least one of the first and second groove ends being at least about 70% less than a width of the groove at a half-way point between the first and second groove ends.
Item 24. A flexible multilayer system for being divided into a plurality of flexible multilayer constructions, each flexible multilayer construction for mounting a different light emitting semiconductor device (LESD), the flexible multilayer system comprising:

a flexible dielectric substrate comprising opposing top and bottom major surfaces;

an electrically conductive layer formed on the top major surface of dielectric substrate, the conductive layer defining
one or more spaced apart parallel wider first grooves extending lengthwise along a first direction; and
one or more spaced apart parallel narrower second grooves extending lengthwise along an orthogonal second direction, each narrower second groove communicating with at least one wider first groove; and

an electrically insulative reflective material at least partially filling each first and second groove.

Item 25. The flexible multilayer system of item 24, wherein each first and second groove extends depthwise to the top major surface of the dielectric substrate.
Item 26. The flexible multilayer system of any of items 24 through 25, wherein the one or more spaced apart parallel wider first grooves comprises at least 20 spaced apart parallel wider first grooves.
Item 27. The flexible multilayer system of any of items 24 through 25, wherein the one or more spaced apart parallel narrower second grooves comprises at least 50 spaced apart parallel narrower second grooves.
Item 28. The flexible multilayer system of any of items 24 through 27, wherein each wider first groove is sufficiently wide that it can reliably be screen printed with a solution of the reflective material without printing the solution beyond a lateral edge of the first groove.
Item 29. The flexible multilayer system of any of items 24 through 28, wherein each narrower second groove is sufficiently narrow that it cannot reliably be screen printed with a solution of the reflective material without printing the solution beyond a lateral edge of the first groove.
Item 30. The flexible multilayer system of any of items 24 through 29, wherein a minimum width of each wider first groove is at least 400 microns, and a maximum width of each narrower second groove is at most 200 microns.
Item 31. The flexible multilayer system of any of claims 24 through 30, wherein when the flexible multilayer system is divided into a plurality of flexible multilayer constructions, each construction comprises an LESD mounting region comprising a narrower second groove of the one or more narrower second grooves having a first portion of the conductive layer on a first lateral side of the second groove and a second portion of the conductive layer on an opposite second lateral side of the second groove, the first and second conductive portions electrically isolated from each other and forming electrically conductive spaced apart respective first and second pads for electrically connecting to corresponding electrically conductive first and second terminals of an LESD received in the LESD mounting region, the reflective material at least partially filling the second groove configured to reflect light emitted by LESD.
Item 32. The flexible multilayer system of any of claims 24 through 31, wherein when the flexible multilayer system is divided into a plurality of flexible multilayer constructions, each flexible multilayer construction includes a section of at least one narrower second groove that is at least partially filled with the electrically insulative reflective material, the filled section of the narrower second groove extends to at least one of first and second edges of the flexile multilayer construction.
Item 33. The flexible multilayer system of any of items 24 through 31, wherein when the flexible multilayer system is divided into a plurality of flexible multilayer constructions, each flexible multilayer construction includes a section of at least one narrower second groove that is at least partially filled with the electrically insulative reflective material, the filled section of the narrower second groove extends to both of first and second edges of the flexile multilayer construction.
Item 34. A flexible multilayer system for being divided into a plurality of flexible multilayer constructions, each flexible multilayer construction for mounting a different light emitting semiconductor device (LESD), the flexible multilayer system comprising a plurality of spaced apart parallel first grooves extending lengthwise along a first direction and a plurality of spaced apart parallel second grooves extending lengthwise along a different second direction, each second groove narrower than each first groove and communicating with at least one first groove, each first and second groove at least partially filled with an electrically insulative reflective material.
Item 35. A flexible multilayer system comprising:

a flexible dielectric substrate comprising opposing top and bottom major surfaces;

a patterned electrically conductive layer disposed on the top surface and defining a plurality of spaced apart capillary grooves, each capillary groove having a width, w, and a depth, d;

an electrically insulative reflective material disposed within the plurality of capillary grooves; and

a plurality of reservoir regions defined by the patterned electrically conductive layer, each reservoir region fluidically coupled to one or more of the capillary grooves and configured to hold an amount of the electrically insulative reflective material to at least partially fill the one or more capillary grooves such that a maximum thickness of the reflective material in the one or more capillary grooves is greater than about 0.7d and less than about 1.2d and a maximum width of the reflective material in the one or more capillary grooves is less than about 1.1w, wherein the width and depth of each capillary groove provides capillary movement of the electrically insulative reflective material within the capillary groove.

Item 36. The flexible multilayer system of item 35, wherein:

each reservoir region has an area that is sufficiently large such that the reservoir region can reliably be screen printed with a solution of the reflective material without printing the solution beyond a lateral edge of the reservoir region; and

each capillary groove is sufficiently narrow that it cannot reliably be screen printed with a solution of the reflective material without printing the solution beyond a lateral edge of the groove.

Item 37. The flexible multilayer system of any of items 35 through 36, wherein:

the plurality of reservoir regions comprises a plurality of spaced apart parallel wider grooves extending along a first direction; and

the plurality of capillary grooves comprises a plurality of narrower parallel grooves extending along a second direction that is different from the first direction.

Item 38. A flexible multilayer construction for mounting an electronic device and comprising electrically conductive spaced apart first and second pads for electrically connecting to corresponding electrically conductive first and second terminals of an electronic device, the first and second pads defining a capillary groove therebetween at least partially filled with an electrically insulative reflective material by a capillary action.
Item 39. The flexible multilayer construction of claim 38, wherein:

the capillary groove has a maximum width less than about 250 microns and a maximum depth d; and

the electrically insulative reflective material fills the capillary groove to a maximum thickness greater than about 0.7d and less than about 1.2d.

Item 40. The flexible multilayer construction of any of items 38 through 39, wherein the maximum width of the capillary groove is w and the maximum width of the filled reflective material is less than about 1.1w.
Item 41. The flexible multilayer construction of any of items 38 through 40, wherein the electrically conductive spaced apart first and second pads are disposed on a dielectric substrate and the capillary groove extends to at least one edge of the dielectric substrate.
Item 42. A method of fabricating one or more multilayer construction for mounting one or more light emitting semiconductor devices (LESD), the method comprising:

providing a flexible dielectric substrate;

forming a patterned electrically conductive layer on a top major surface of dielectric substrate, the patterned conductive layer defining:
a wider first groove; and
a narrower second groove communicating with the wider first groove; and

depositing a solution of an electrically insulative reflective material in the wider first groove, the narrower second groove sufficiently narrow to provide a capillary action so that the solution of the reflective material deposited in the wider first groove flows into the narrower second groove by capillary action and at least partially fills the narrower second groove.

Item 43. The method of item 42, wherein the flexible substrate comprises one or more of polyimide (PI), thermoplastic PI, aromatic polyamide, liquid crystal polymer (LCP), polycarbonate (PC), polyether ether ketone, polyethylene terephthalate (PET), polymethyl methacrylate (PMMA), polycyclic olefin, polysulfone (PSU), polyethylene naphthalate (PEN), epoxy resin, and thermoplastic dielectric material.
Item 44. The method of any of items 42 through 43, wherein the step of patterning the conductive layer comprises one or more of a lithography process, a plating process, a printing process, a coating process, and an etching process.
Item 45. The method of any of items 42 through 44, wherein the step of depositing the solution of reflective material in the wider first groove comprises screen printing the solution in the wider first groove.
Item 46. The method of any of items 42 through 45, wherein the solution of the electrically insulative reflective material is substantially solventless.
Item 47. The method of any of items 42 through 45, wherein the solution of the electrically insulative reflective material comprises less than 5% solvent by weight.
Item 48. The method of any of items 42 through 47, further comprising the step of pre-curing the solution of the electrically insulative reflective material to increase a viscosity of the solution.
Item 49. The method of item 48, wherein the step of pre-curing the solution comprises heating the solution.
Item 50. The method of item 49, wherein the step of heating the solution comprises elevating a temperature of the solution to about 40 to 60 degrees Celsius.
Item 51. The method of item 49, wherein the step of heating the solution comprises elevating a temperature of the solution to about 50 degrees Celsius.
Item 52. The method of item 49, wherein the solution is heated for about 2 to 4 hours.
Item 53. The method of any of items 42 through 52, further comprising a step of maintaining a temperature of the dielectric substrate at a temperature greater than a room temperature during the deposition of the reflective material in the wider first groove and the capillary flow of the deposited reflective material into the narrower second groove.
Item 54. The method of item 53, wherein the temperature of the dielectric substrate is maintained in a range from about 30 to 80 degrees Celsius.
Item 55. The method of item 53, wherein the temperature of the dielectric substrate is maintained in a range from about 40 to 70 degrees Celsius.
Item 56. The method of item 53, wherein the temperature of the dielectric substrate is maintained in a range from about 45 to 70 degrees Celsius.
Item 57. The method of item 53, wherein the temperature of the dielectric substrate is maintained in a range from about 50 to 70 degrees Celsius.
Item 58. The method of item 53, wherein the step of maintaining the temperature of the dielectric substrate at a temperature greater than the room temperature increases a speed of the capillary flow of the deposited reflective material into the narrower second groove by at least a factor of 10.
Item 59. The method of item 53, wherein the step of maintaining the temperature of the dielectric substrate at a temperature greater than the room temperature increases a speed of the capillary flow of the deposited reflective material into the narrower second groove by at least a factor of 50.
Item 60. The method of item 53, wherein the step of maintaining the temperature of the dielectric substrate at a temperature greater than the room temperature increases a speed of the capillary flow of the deposited reflective material into the narrower second groove by at least a factor of 100.
Item 61. The method of any of items 42 through 60, further comprising a step of depositing the solution of the electrically insulative reflective material in the wider first groove a second time, the deposited solution further filling the narrower second groove by capillary action.
Item 62. The method of item 61, further comprising maintaining a temperature of the dielectric substrate at a temperature greater than a room temperature during the second deposition of the reflective material in the wider first groove and the capillary flow of the deposited reflective material into the narrower second groove.
Item 63. The method of item 61, wherein the step of depositing the reflective material a second time increases a thickness of the reflective material in the wider first groove and the narrower second groove.
Item 64. The method of item 63, wherein the thickness of the reflective material increase more in the wider first groove and less in the narrower second groove.
Item 65. The method of any of items 42 through 64, further comprising a step of curing the reflective material after the deposition of the reflective material in the wider first groove and the capillary flow of the deposited reflective material into the narrower second groove.
Item 66. The method of item 65, wherein the curing step comprises increasing a temperature of the reflective material to about 130 to about 170 degrees Celsius.
Item 67. The method of item 66, wherein the increased temperature is maintained for about 1 to 3 hours.
Item 68. The method of item 65, wherein the curing step comprises increasing a temperature of the reflective material to about 140 to about 170 degrees Celsius.
Item 67. The method of item 65, wherein the curing step comprises exposing the reflective material to UV radiation.
Item 68. The method of any of items 42 through 67, wherein the wider first groove extends lengthwise along a first direction, and the narrower second groove extends lengthwise along a different second direction.
Item 69. The method of any of items 42 through 68, wherein the patterned conductive layer defines:

a plurality of wider first grooves; and

a plurality of narrower second grooves, each narrower second groove communicating with at least one wider first groove.

Item 70. The method of item 69, wherein the step of depositing the solution of the electrically insulative reflective material comprises depositing the solution in each wider first groove, the narrower second grooves sufficiently narrow to provide capillary action so that the solution of the reflective material deposited in each wider first groove flows into at least one narrower second groove in communication with the wider first groove by capillary action and at least partially fills the at least one narrower second groove.
Item 71. The method of any of items 42 through 70, wherein the electrically insulative reflective material comprises one or more of epoxy, polyurethane, polyimide and polysilicon.
Item 72. The method of any of items 42 through 71, further comprising dividing the flexible dielectric substrate having the patterned electrically conductive layer formed thereon into a plurality of the multilayer constructions.

Various modifications and alterations of this invention will be apparent to those skilled in the art and it should be understood that this scope of this disclosure is not limited to the illustrative embodiments set forth herein. For example, the reader should assume that features of one disclosed embodiment can also be applied to all other disclosed embodiments unless otherwise indicated.

1-16. (canceled)

17. A flexible multilayer construction for mounting a light emitting semiconductor device (LESD), comprising:
a flexible dielectric substrate comprising opposing top and bottom major surfaces and an LESD mounting region on the top major surface;
electrically conductive spaced apart first and second pads disposed in the LESD mounting region for electrically connecting to corresponding electrically conductive first and second terminals of an LESD received in the LESD mounting region, the first and second pads defining a groove therebetween having a maximum width less than about 250 microns and a maximum depth d; and
an electrically insulative reflective material at least partially filling the groove to a maximum thickness greater than about 0.7d and less than about 1.2d and a maximum width less than about 270 microns.

18. The flexible multilayer construction of claim 17, wherein the maximum width of the groove is less than about 100 microns.

19. The flexible multilayer construction of claim 17, wherein d is in a range from about 10 microns to 70 microns.

20. The flexible multilayer construction of claim 17, wherein the maximum width of the groove is w and the maximum width of the filled reflective material is less than about 1.1w.

21. The flexible multilayer construction of claim 17, wherein if, when the reflective material is at least partially filling the groove, some of the reflective material is placed on a top surface of either the first or second pad, the placement is limited to within 20 microns of the groove.

22. The flexible multilayer construction of claim 17, wherein the reflective material at least partially fills the groove by capillary action.

23. The flexible multilayer construction of claim 17 having an average optical transmittance of less than about 25% in a visible range of the spectrum at a location on the filled reflective material inside lateral edges of the groove.

24. The flexible multilayer construction of claim 17 having an average optical reflectance of greater than about 70% in a visible range of the spectrum at a location on the filled reflective material inside lateral edges of the groove.

25. The flexible multilayer construction of claim 17 having an average optical reflectance of greater than about 80% in a visible range of the spectrum at a location on the filled reflective material inside lateral edges of the groove.

26. A flexible multilayer system for being divided into a plurality of flexible multilayer constructions, each flexible multilayer construction for mounting a different light emitting semiconductor device (LESD), the flexible multilayer system comprising:
a flexible dielectric substrate comprising opposing top and bottom major surfaces;
an electrically conductive layer formed on the top major surface of dielectric substrate, the conductive layer defining
one or more spaced apart parallel wider first grooves extending lengthwise along a first direction; and
one or more spaced apart parallel narrower second grooves extending lengthwise along an orthogonal second direction, each narrower second groove communicating with at least one wider first groove; and
an electrically insulative reflective material at least partially filling each first and second groove.

27. The flexible multilayer system of claim 26, wherein when the flexible multilayer system is divided into a plurality of flexible multilayer constructions, each construction comprises an LESD mounting region comprising a narrower second groove from the one or more second grooves having a first portion of the conductive layer on a first lateral side of the second groove and a second portion of the conductive layer on an opposite second lateral side of the second groove, the first and second conductive portions electrically isolated from each other and forming electrically conductive spaced apart respective first and second pads for electrically connecting to corresponding electrically conductive first and second terminals of an LESD received in the LESD mounting region, the reflective material at least partially filling the second groove configured to reflect light emitted by LESD.

28. A flexible multilayer system for being divided into a plurality of flexible multilayer constructions, each flexible multilayer construction for mounting a different light emitting semiconductor device (LESD), the flexible multilayer system comprising a plurality of spaced apart parallel first grooves extending lengthwise along a first direction and a plurality of spaced apart parallel second grooves extending lengthwise along a different second direction, each second groove narrower than each first groove and communicating with at least one first groove, each first and second groove at least partially filled with an electrically insulative reflective material.

29. A flexible multilayer system comprising:
a flexible dielectric substrate comprising opposing top and bottom major surfaces;
a patterned electrically conductive layer disposed on the top surface and defining a plurality of spaced apart capillary grooves, each capillary groove having a width, w, and a depth, d;
an electrically insulative reflective material disposed within the plurality of capillary grooves; and
a plurality of reservoir regions defined by the patterned electrically conductive layer, each reservoir region fluidically coupled to one or more of the capillary grooves and configured to hold an amount of the electrically insulative reflective material to at least partially fill the one or more capillary grooves such that a maximum thickness of the reflective material in the one or more capillary grooves is greater than about 0.7d and less than about 1.2d and a maximum width of the reflective material in the one or more capillary grooves is less than about 1.1w, wherein the width and depth of each capillary groove provides capillary movement of the electrically insulative reflective material within the capillary groove.

30. The flexible multilayer system of claim 29, wherein:
each reservoir region has an area that is sufficiently large such that the reservoir region can reliably be screen printed with a solution of the reflective material without printing the solution beyond a lateral edge of the reservoir region; and
each capillary groove is sufficiently narrow that it cannot reliably be screen printed with a solution of the reflective material without printing the solution beyond a lateral edge of the groove.

31. A flexible multilayer construction for mounting an electronic device and comprising electrically conductive spaced apart first and second pads for electrically connecting to corresponding electrically conductive first and second terminals of an electronic device, the first and second pads defining a capillary groove therebetween at least partially filled with an electrically insulative reflective material by a capillary action.

32. The flexible multilayer construction of claim 31, wherein the electrically conductive spaced apart first and second pads are disposed on a dielectric substrate and the capillary groove extends to at least one edge of the dielectric substrate.

33. A method of fabricating one or more multilayer construction for mounting one or more light emitting semiconductor devices (LESD), the method comprising:
providing a flexible dielectric substrate;
forming a patterned electrically conductive layer on a top major surface of dielectric substrate, the patterned conductive layer defining:
a wider first groove; and
a narrower second groove communicating with the wider first groove; and
depositing a solution of an electrically insulative reflective material in the wider first groove, the narrower second groove sufficiently narrow to provide a capillary action so that the solution of the reflective material deposited in the wider first groove flows into the narrower second groove by capillary action and at least partially fills the narrower second groove.

34. The method of claim 33 further comprising a step of maintaining a temperature of the dielectric substrate at a temperature greater than a room temperature during the deposition of the reflective material in the wider first groove and the capillary flow of the deposited reflective material into the narrower second groove.

35. The method of claim 33, further comprising a step of depositing the solution of the electrically insulative reflective material in the wider first groove a second time, the deposited solution further filling the narrower second groove by capillary action.

36. The method of claim 33, wherein the patterned conductive layer defines:
a plurality of wider first grooves; and
a plurality of narrower second grooves, each narrower second groove communicating with at least one wider first groove, and wherein the step of depositing the solution of the electrically insulative reflective material comprises depositing the solution in each wider first groove, the narrower second grooves sufficiently narrow to provide capillary action so that the solution of the reflective material deposited in each wider first groove flows into at least one narrower second groove in communication with the wider first groove by capillary action and at least partially fills the at least one narrower second groove.
